(19) United States
(12) Patent Application Publication
(10) Pub. No.: US 2006/0220707 A1
(43) Pub. Date: Oct. 5, 2006

(54) Output driver for semiconductor device

(75) Inventors: Hee-Bok Kang, Ichon-shi (KR); Jin-Hong Ahn, Ichon-shi (KR)

Correspondence Address: MCDERMOTT WILL & EMERY LLP, 600 13TH STREET, N.W., WASHINGTON, DC, 20005-3096, US

(73) Assignee: Hynix Semiconductor Inc.

(21) Appl. No.: 11/304,823

(22) Filed: Dec. 16, 2005

(30) Foreign Application Priority Data
Mar. 31, 2005 (KR) 2005-0027339

(51) Int. Cl. H03B 1/00

(52) U.S. Cl. 327/112

(57) ABSTRACT

There are provided an output driver for a semiconductor device for securing the constant pull-up and pull-down drivability regardless of temperature condition and process characteristic. The output driver for a semiconductor device includes a first driving unit for transmitting an output data; a detecting unit for detecting at least one of a temperature condition and a process characteristic; an auxiliary pull-up driving unit for pulling up a level of the output data in response to the detection result of the detecting unit; and an auxiliary pull-down driving unit for pulling down the level of the output data in response to the detection result of the detecting unit.

### FIELD OF THE INVENTION

The present invention relates to a semiconductor design technology; and, more particularly, to an output driver for a semiconductor device.

### DESCRIPTION OF RELATED ART

Semiconductor devices are fabricated using overall semiconductor technologies, including a silicon wafer processing technology and a logic design technology. Final products of the semiconductor fabrication process are plastic package type chips. They have different logics and functions depending on objects of use. Most of semiconductor chips are mounted on printed circuit board (PCB), which is an important element in a system configuration, and appropriate driving voltages are supplied to them.

All semiconductor devices including semiconductor memory devices are operated according to input/output of specific signals. That is, the operations and operating methods of the semiconductor devices are determined by a combination of these input signals. Also, their results are outputted according to the flow of the output signals. Meanwhile, an output signal of a certain semiconductor device may be used as an input signal of another semiconductor device within the same system.

FIG. 1 is a circuit diagram of an input/output interface unit in a conventional semiconductor device.

Referring to FIG. 1, the input/output interface unit 10 of the semiconductor device includes an input buffer 12 and an output driver 14.

The input buffer 12 buffers an external signal inputted through an input terminal DQ and inputs the buffered signal to the inside of the semiconductor device. A static input buffer and a differential input buffer are generally used as the input buffer 12.

Meanwhile, the output driver 14 drives an output terminal DQ and a load connected thereto by using an output data of the semiconductor device. A CMOS inverter type main driver is used as the output driver 14. The CMOS inverter type main driver is configured with a pull-up PMOS transistor and a pull-down NMOS transistor, which are connected in series between a source voltage and a ground voltage. Also, a pre-driver may be provided in a previous stage of the main driver.

As an operating voltage of the semiconductor device is lower and an operating speed is faster, performance of the output driver is important in association with signal integrity. It is because voltage level and slew rate of the output data are determined by the output driver.

In such a conventional output driver, a current drivability of the pull-up transistor and the pull-down transistor is different depending on temperature condition and process characteristic. In general, the operation characteristic is divided into a best case, a typical case, a worst case. In the worst case, the drivability in the output terminal DQ of the output driver is low. In addition, when temperature is high, the drivability is also degraded. The low drivability of the output driver is a factor that degrades the output characteristic of the semiconductor device.

### SUMMARY OF THE INVENTION

It is, therefore, an object of the present invention to provide an output driver for a semiconductor device for securing a constant pull-up and pull-down drivability regardless of process characteristic or temperature condition.

In accordance with an aspect of the present invention, there is provided an output driver of a semiconductor device including: a first driving unit for transmitting an output data; and a second driving unit for controlling the output data based on at least one of a temperature condition and a process characteristic in order to stabilize the output data.

In accordance with another aspect of the present invention, there is provided a semiconductor memory device for stably driving an output data including: a first driving unit for transmitting an output data; a detecting unit for detecting at least one of a temperature condition and a process characteristic; and a second driving unit for controlling the output data based on detection result of the detecting unit in order to stabilize the output data.

### BRIEF DESCRIPTION OF THE DRAWINGS

The above and other objects and features of the present invention will become apparent from the following description of the preferred embodiments given in conjunction with the accompanying drawings, in which:

FIG. 1 is a circuit diagram of a data input/output interface unit in a conventional semiconductor device;

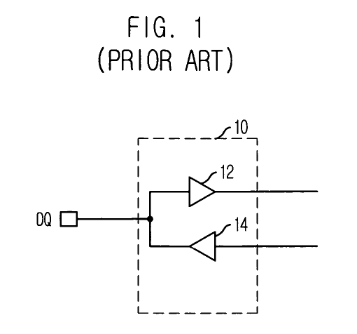

FIG. 2 is a circuit diagram of an output driver in accordance with an embodiment of the present invention;

FIG. 3 is a pull-up current curve with respect to an operation characteristic-temperature condition; and

FIG. 4 is a pull-down current curve with respect to an operation characteristic-temperature condition.

### DETAILED DESCRIPTION OF THE INVENTION

Other objects and aspects of the invention will become apparent from the following description of the embodiments with reference to the accompanying drawings, which is set forth hereinafter.

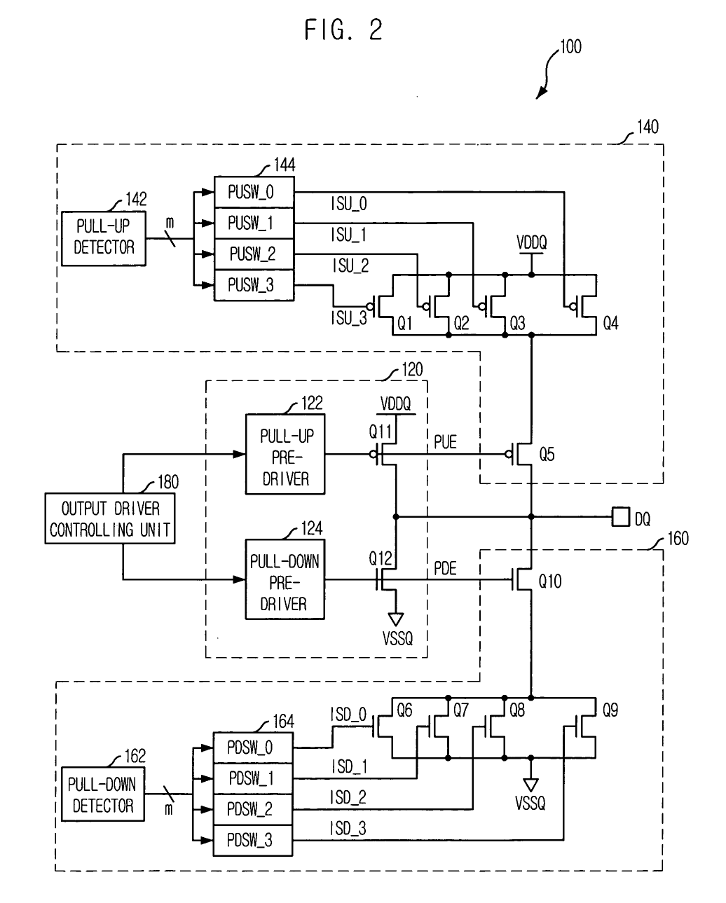

FIG. 2 is a circuit diagram of an output driver in accordance with an embodiment of the present invention.

Referring to FIG. 2, the output driver 100 includes a main driving unit 120, an auxiliary driving unit 140 and 160. The main driving unit 120 drives an output terminal by using an output data of an output driver controlling unit 180. The auxiliary driving unit 140 and 160 auxiliarily drives the output terminal DQ by using an amount of a current depending on temperature condition and process characteristic.

Also, the main driving unit 120 includes a pull-up pre-driver 122, a pull-down pre-driver 124, a main pull-up driver PMOS transistor Q11, and a main pull-down driver NMOS transistor Q12. The pull-up pre-driver 122 pre-drives the output data to generate a pull-up control signal PUE, and the pull-down pre-driver 124 pre-drives the output data to generate a pull-down control signal PDE. The main pull-up driver PMOS transistor Q11 pulls up the output terminal DQ in response to the pull-up control signal PUE, and the main pull-down driver NMOS transistor Q12 pulls down the output terminal DQ in response to the pull-down control signal PDE.

The auxiliary driving unit 140 and 160 is used for controlling the drivability and includes an auxiliary pull-up driving unit 140 and an auxiliary pull-down driving unit 160. The auxiliary pull-up driving unit 140 auxiliarily pulls up the output terminal DQ by using the amount of the current depending on the temperature condition and the process characteristic. The auxiliary pull-down driving unit 160 auxiliarily pulls down the output terminal DQ by using the amount of the current depending on the temperature condition and the process characteristic.

The auxiliary pull-up driving unit 140 is provided for controlling the pull-up drivability of the output terminal DQ in each step, depending on the temperature condition and the process characteristic. The auxiliary pull-up driving unit 140 includes a pull-up (PU) detector 142, a first decoder 144, a plurality of driver PMOS transistors Q4, Q3, Q2 and Q1, and an auxiliary pull-up driver PMOS transistor Q5. The pull-up (PU) detector 142 detects the temperature condition and the process characteristic. The first decoder 144 decodes an m-bit output value (m is a positive integer, m=2 in this embodiment) of the pull-up detector 142. The driver PMOS transistors Q4, Q3, Q2 and Q1 are connected in parallel to a source voltage VDDQ supply. Each gate of the driver PMOS transistors Q4, Q3, Q2 and Q1 receives the output signals ISU_0, ISU_1, ISU_2 and ISU_3 of the first decoder 144, respectively. The auxiliary pull-up driver PMOS transistor Q5 is connected between the output terminal DQ and the driver PMOS transistors Q4, Q3, Q2 and Q1, and has a gate receiving the pull-up control signal PUE. Preferably, all the driver PMOS transistors Q4, Q3, Q2 and Q1 of the auxiliary pull-up driving unit 140 are designed with the equal size.

The auxiliary pull-down driving unit 160 is provided for controlling the pull-down drivability of the output terminal DQ in each step, depending on the temperature condition and the process characteristic. The auxiliary pull-down driving unit 160 includes a pull-down (PD) detector 162, a second decoder 164, a plurality of driver NMOS transistors Q6, Q7, Q8 and Q9, and an auxiliary pull-down driver NMOS transistor Q10. The pull-down (PD) detector 162 detects the temperature condition and the process characteristic. The second decoder 164 decodes an m-bit output value of the pull-down detector 162. The driver NMOS transistors Q6, Q7, Q8 and Q9 are connected in parallel to a ground voltage supply VSSQ. Gates of the driver NMOS transistors Q6, Q7, Q8 and Q9 receive the output signals ISD_0, ISD_1, ISD_2 and ISD_3 of the second decoder 164, respectively. The auxiliary pull-down driver NMOS transistor Q10 is connected between the output terminal DQ and the driver NMOS transistors Q6, Q7, Q8 and Q9, and has a gate receiving the pull-down control signal PDE. Preferably, all the driver NMOS transistors Q6, Q7, Q8 and Q9 of the auxiliary pull-down driving unit 160 are designed with the equal size.

Each of the pull-up detector 142 and the pull-down detector 162 can be configured with a temperature sensor, a process characteristic sensor, and a binary adder for adding outputs of the two sensors.

Meanwhile, the first decoder 144 is a 2×4 decoder. PUSW_0, PUSW_1, PUSW_2 and PUSW_3 represent four switching elements each of which receives a different combination of 2-bit values outputted from the pull-up detector 142. These switching elements can be configured with a NAND gate and so on. The second decoder 164 is a 2×4 decoder. PDSW_0, PDSW_1, PDSW_2 and PDSW_3 represent four switching elements each of which receives a different combination of 2-bit values outputted from the pull-down detector 162. These switching elements can be configured with a NAND gate and so on.

Tables 1 to 3 below show exemplary controls of the pull-up drivability in the output driver 100 of FIG. 2 according to the process characteristic and the temperature condition. An operation of the output driver 100 in accordance with the present invention will be described below with reference to Tables 1 to 3.

TABLE 1

| | Temperature | | | | |
|---|---|---|---|---|---|
| Process | Condition | | | | |
| Characteristic | (° C.) | ISU_0 | ISU_1 | ISU_2 | ISU_3 |
| Best Case | <−10 | H | H | H | H |
| | −10-25 | L | H | H | H |
| | 25-55 | L | L | H | H |
| | >55 | L | L | L | H |

TABLE 2

| | Temperature | | | | |
|---|---|---|---|---|---|
| Process | Condition | | | | |
| Characteristic | (° C.) | ISU_0 | ISU_1 | ISU_2 | ISU_3 |
| Typical Case | <−10 | L | H | H | H |
| | −10-25 | L | L | H | H |
| | 25-55 | L | L | L | H |
| | >55 | L | L | L | L |

TABLE 3

| | Temperature | | | | |
|---|---|---|---|---|---|
| Process | Condition | | | | |
| Characteristic | (° C.) | ISU_0 | ISU_1 | ISU_2 | ISU_3 |
| Worst Case | <−10 | L | L | H | H |
| | −10-25 | L | L | L | H |
| | 25-55 | L | L | L | L |
| | >55 | L | L | L | L |

It will be assumed that the pull-up control signal PUE is activated to a logic low level.

Table 1 shows logic levels of the output signals ISU_0, ISU_1, ISU_2 and ISU_3 of the first decoder 144 in the auxiliary pull-up driving unit 140 when the process characteristic is the best case, depending on the respective temperature conditions.

Referring to Table 1, all the driver PMOS transistors Q1, Q2, Q3 and Q4 are turned off under the temperature condition of below −10° C., and only one transistor Q4 is turned on under the temperature condition of −10° C. to 25° C. Two transistors Q4 and Q3 are turned on under the temperature condition of 25° C. to 55° C., and three transistors Q4, Q3 and Q2 are turned on under the temperature condition of above 55° C. Therefore, the turned-on transistor(s) forms a current path together with the auxiliary pull-up driver PMOS transistor Q5. That is, in the best case of the process characteristic, a current drivability of the main pull-up driver PMOS transistor Q11 is secured somewhat. Therefore, the auxiliary pull-up driver PMOS transistor Q5 does not have to operate at a low temperature. As the temperature increases higher, more transistors are turned on stepwise. Therefore, the constant pull-up drivability can be secured regardless of the process characteristic and the temperature condition.

Table 2 shows logic levels of the output signals ISU_0, ISU_1, ISU_2 and ISU_3 of the first decoder 144 in the auxiliary pull-up driving unit 140 when the process characteristic is the typical case, depending on the respective temperature conditions.

Referring to Table 2, only one transistor Q4 is turned on under the temperature condition of below −10° C., and two transistors Q4 and Q3 are turned on under the temperature condition of −10° C. to 25° C. Three transistors Q4, Q3 and Q2 are turned on under the temperature condition of 25° C. to 55° C., and all the driver PMOS transistors Q1, Q2, Q3 and Q4 are turned on under the temperature condition of above 55° C. Therefore, the turned-on transistor(s) forms a current path together with the auxiliary pull-up driver PMOS transistor Q5. That is, in the typical case of the process characteristic, a current drivability of the main pull-up driver PMOS transistor Q11 is typical. Therefore, by turning on more transistors compared with the best case, the constant pull-up drivability can be secured regardless of the process characteristic and the temperature condition.

Table 3 shows logic levels of the output signals ISU_0, ISU_1, ISU_2 and ISU_3 of the first decoder 144 in the auxiliary pull-up driving unit 140 when the process characteristic is the worst case, depending on the respective temperature conditions.

Referring to Table 3, two transistors Q4 and Q3 are turned on under the temperature condition of below −10° C., and three transistors Q4, Q3 and Q2 are turned on under the temperature condition of −10° C. to 25° C. All the driver PMOS transistors Q1, Q2, Q3 and Q4 are turned on under the temperature condition of 25° C. to 55° C. and above 55° C. Therefore, the turned-on transistors form a current path together with the auxiliary pull-up driver PMOS transistor Q5. That is, in the worst case of the process characteristic, a current drivability of the main pull-up driver PMOS transistor Q11 is lowered. Therefore, by turning on more transistors compared with the typical case, the constant pull-up drivability can be secured regardless of the process characteristic and the temperature condition. Meanwhile, the equal current drivability is exhibited under the temperature condition of 25° C. to 55° C. and above 55° C. In this embodiment, it can be understood that the maximum value is selected according as four driver PMOS transistors Q1, Q2, Q3 and Q4 are provided.

As described above, an amount of a current flowing through the auxiliary pull-up driver PMOS transistor Q5 is controlled depending on the process characteristic and the temperature condition. That is, the drivability due to the auxiliary pull-up driver PMOS transistor Q5 is made to relatively decrease when the process characteristic and the temperature condition are good, and it is made to relatively increase when they are bad. In this manner, the degradation in the drivability of the main pull-up driver PMOS transistor Q11 can be compensated.

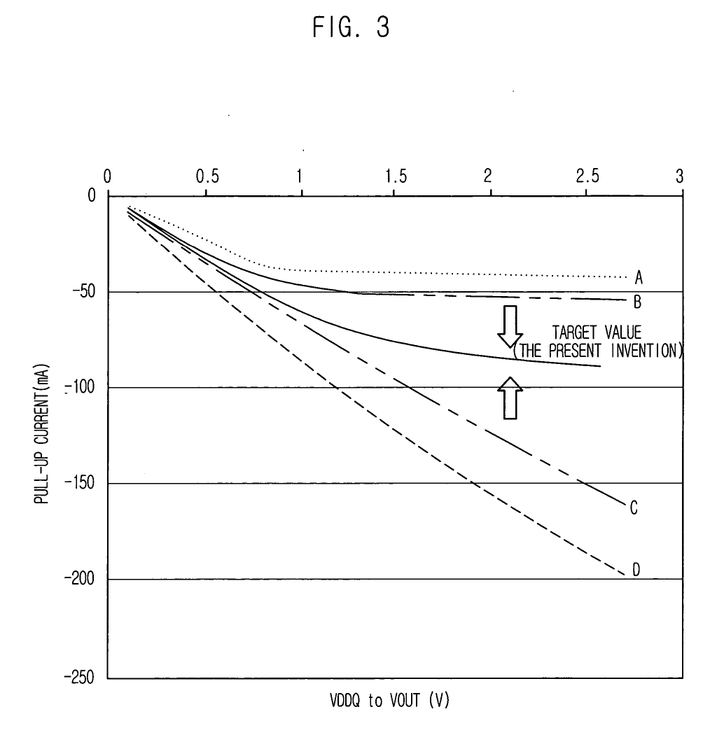

FIG. 3 is a pull-up current curve with respect to an operation characteristic-temperature condition.

As illustrated in FIG. 3, the pull-up drivability for the output terminal DQ can be maintained constantly depending on the process characteristic and the temperature condition.

In FIG. 3, A, B, C and D represent pull-up current curves when the process characteristic and the temperature condition are worst, bad, good, and best, respectively. These curves are results according to the prior art. However, when the present invention is applied, the pull-up current curve can exhibit the desired target value.

Meanwhile, since the operations according to the temperature and the process characteristic are dependent on the 2-bit output value of the pull-up detector 142, the 2-bit output value must be able to be generated through a combination of the detection results of the temperature sensor and the process characteristic sensor within the pull-up detector 142. An example of the pull-up detector 142 satisfying Tables 1 to 3 will be described below.

For the best/typical/worst cases, the process characteristic sensor of the pull-up detector 142 outputs ‘01/11/01’ as its detection result. Also, the temperature sensor outputs ‘00/01/10/11’ as its detection results with respect to four steps of Tables 1 to 3. The binary adder of the pull-up detector 142 adds the two output values.

For example, when the typical process characteristic is typical and the temperature condition is 25° C. to 55° C., the output value of the process characteristic sensor is ‘00’ and the output value of the temperature sensor is ‘10’. Therefore, the 2-bit output value of the first pull-up detector 142 is ‘10’. The output signal of the first decoder 144 is ‘0011’ when the 2-bit output value of the pull-up detector 142 is ‘00’, and the output signal of the first decoder 144 is ‘0011’ when the 2-bit output value of the pull-up detector 142 is ‘01’. The output signal of the first decoder 144 is ‘0001’ when the 2-bit output value of the pull-up detector 142 is ‘10’, and the output signal of the first decoder 144 is ‘0000’ when the 2-bit output value of the pull-up detector 142 is ‘11’. Consequently, the output signal of the first decoder 144 is ‘0001’, so that three transistors Q4, Q3 and Q2 of the driver PMOS transistors Q1, Q2, Q3 and Q4 are turned on (refer to Table 2). Meanwhile, assuming that the first decoder 144 is disabled when the 2-bit output value of the pull-up detector 142 is negative like when the process characteristic is best and the temperature condition is below −10° C., all the PMOS transistors Q1, Q2, Q3 and Q4 can be turned off.

Tables 4 to 6 below show exemplary controls of the pull-up drivability in the output driver 100 of FIG. 2 according to the process characteristic and the temperature condition.

TABLE 4

| | Temperature | | | | |
|---|---|---|---|---|---|
| Process | Condition | | | | |
| Characteristic | (° C.) | ISD_0 | ISD_1 | ISD_2 | ISD_3 |
| Best Case | <−10 | L | L | L | L |
| | −10-25 | H | L | L | L |
| | 25-55 | H | H | L | L |
| | >55 | H | H | H | L |

TABLE 5

| | Temperature | | | | |
|---|---|---|---|---|---|
| Process | Condition | | | | |
| Characteristic | (° C.) | ISD_0 | ISD_1 | ISD_2 | ISD_3 |
| Typical Case | <−10 | H | L | L | L |
| | −10-25 | H | H | L | L |
| | 25-55 | H | H | H | L |
| | >55 | H | H | H | H |

TABLE 6

| | Temperature | | | | |
|---|---|---|---|---|---|
| Process | Condition | | | | |
| Characteristic | (° C.) | ISD_0 | ISU_1 | ISU_2 | ISU_3 |
| Worst Case | <−10 | H | H | L | L |
| | −10-25 | H | H | H | L |
| | 25-55 | H | H | H | H |
| | >55 | H | H | H | H |

Table 4 shows logic levels of the output signals ISD_0, ISD_1, ISD_2 and ISD_3 of the second decoder 164 in the auxiliary pull-down driving unit 160 when the process characteristic is the best case, depending on the respective temperature conditions. Table 5 shows logic levels of the output signals ISD_0, ISD_1, ISD_2 and ISD_3 of the second decoder 164 in the auxiliary pull-down driving unit 160 when the process characteristic is the typical case, depending on the respective temperature conditions. Table 6 shows logic levels of the output signals ISD_0, ISD_1, ISD_2 and ISD_3 of the second decoder 164 in the auxiliary pull-down driving unit 160 when the process characteristic is the worst case, depending on the respective temperature conditions.

Since data of Tables 4 to 6 has opposite polarities to data of Tables 1 to 3, the number of the driver NMOS transistors Q6, Q7, Q8 and Q9 selected according to the respective conditions is equal. Accordingly, the pull-down detector 162 satisfying Tables 4 to 6 can be implemented with the same structure as that of the pull-up detector 142. At this point, the second decoder 164 is configured to have the polarity opposite to that of the first decoder 144.

The pull-down operation of the output driver according to Tables 4 to 6 is equal to the above-described pull-up operation. That is, in this embodiment, the output driver controls an amount of a current flowing through the auxiliary pull-down driver NMOS transistor Q10 depending on the operation characteristic and the temperature condition during the pull-down operation. The drivability due to the auxiliary pull-down driver NMOS transistor Q10 is made to relatively decrease when the process characteristic and the temperature condition are good, and it is made to relatively increase when they are bad. In this manner, the degradation in the drivability of the pull-down NMOS transistor Q12 can be compensated.

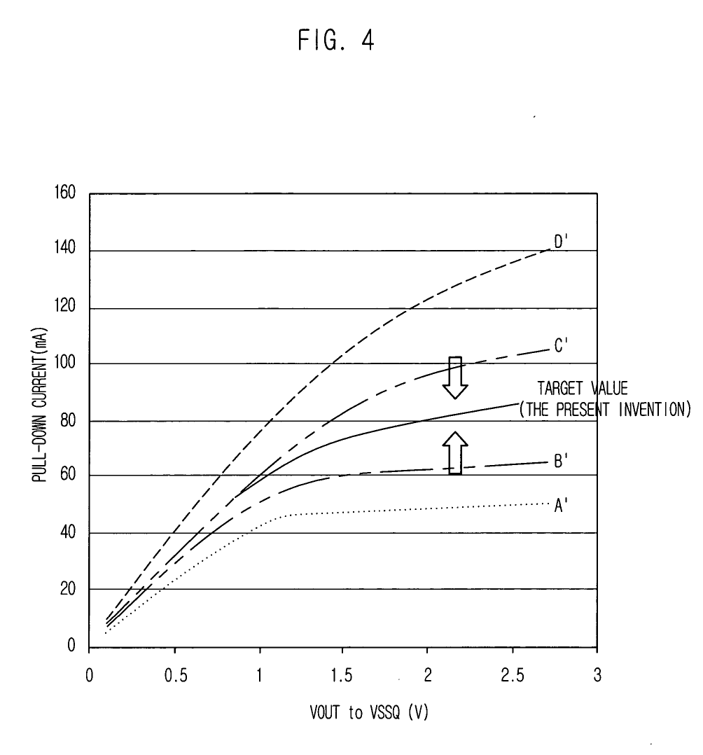

FIG. 4 is a pull-down current curve with respect to an operation characteristic-temperature condition.

As illustrated in FIG. 4, the pull-down drivability for the output terminal DQ can be maintained constantly depending on the process characteristic and the temperature condition.

In FIG. 4, A′, B′, C′ and D′ represent pull-down current curves when the process characteristic and the temperature condition are worst, bad, good, and best, respectively. These curves are results according to the prior art. However, when the present invention is applied, the pull-down current curve can exhibit the desired target value.

Meanwhile, as described above, if the pull-up detector 142 and the pull-down detector 162 are implemented with the equal structures, the auxiliary pull-up driving unit 140 and the auxiliary pull-down driving unit 160 need not have the detector. Therefore, the auxiliary pull-up driving unit 140 and the auxiliary pull-down driving unit 160 can share one detector.

If necessary, it is necessary to differently control the pull-up drivability and the pull-down drivability. In this case, the drivability of the pull-up side and the pull-down side can be differently controlled by making the pull-up driver 142 and the pull-down driver 162 have the different outputs.

In the above-described embodiment, although the auxiliary pull-up and pull-down driving units 140 and 160 use four driver PMOS transistors and four driver NMOS transistors, respectively, the driver transistors can use transistors of opposite polarity and the number of the driver transistors can be changed.

In addition, although both the temperature sensor and the process characteristic sensor are applied for considering the temperature condition and the process characteristic, only one of them can be applied.

As described above, the pull-up and pull-down drivability can be secured regardless of the process characteristic and the temperature condition. Thus, the signal integrity of the output driver can be secured and the reliability of the semiconductor device can be improved.

The present application contains subject matter related to Korean patent application No. 2005-27339, filed in the Korean Intellectual Property Office on Mar. 31, 2005, the entire contents of which is incorporated herein by reference.

While the present invention has been described with respect to certain preferred embodiments, it will be apparent to those skilled in the art that various changes and modifications may be made without departing from the scope of the invention as defined in the following claims.

What is claimed is:

1. An output driver of a semiconductor device, comprising:
a first driving unit for transmitting an output data; and
a second driving unit for controlling the output data based on at least one of a temperature condition and a process characteristic in order to stabilize the output data.

2. The output driver as recited in claim 1, wherein the first driving unit includes:
a pull-up pre-driver for pre-driving the output data to generate a pull-up control signal;
a pull-down pre-driver for pre-driving the output data to generate a pull-down control signal;
a main pull-up driver for pulling up a level of the output data in response to the pull-up control signal; and
a main pull-down driver for pulling down the level of the output data in response to the pull-down control signal.

3. The output driver as recited in claim 1, wherein the second driving unit includes:
a detecting unit for detecting at least one of the temperature condition and the process characteristic;
an auxiliary pull-up driving unit for pulling up the level of the output data in response to detection result of the detecting unit; and
an auxiliary pull-down driving unit for pulling down the level of the output data in response to the detection result of the detecting unit.

4. The output driver as recited in claim 3, wherein the detecting unit includes:
a temperature sensor for detecting the temperature condition;
a process characteristic sensor for detecting the process characteristic; and
an adder for adding outputs of the temperature sensor and the process characteristic sensor.

5. The output driver as recited in claim 3, wherein the detecting unit includes:
a first detector for detecting the temperature condition and the process characteristic to generate a first output value; and
a second detector for detecting the temperature condition and the process characteristic to generate a second output value different from the first output value.

6. The output driver as recited in claim 5, wherein the first detector includes:
a first temperature sensor for detecting the temperature condition;
a first process characteristic sensor for detecting the process characteristic; and
an adder for adding outputs of the first temperature sensor and the first process characteristic sensor.

7. The output driver as recited in claim 6, wherein the second detector includes:
a second temperature sensor for detecting the temperature characteristic to output an output value different from that of the first temperature sensor;
a second temperature sensor for detecting the process characteristic to output an output value different from that of the first process characteristic sensor; and
a second binary adder for adding outputs of the second temperature sensor and the second process characteristic sensor.

8. The output driver as recited in claim 4, wherein the auxiliary pull-up driving unit includes:
a first decoder for decoding the first output value of the first detector;
an auxiliary pull-up driver for pulling up the level of the output data in response to the pull-up control signal; and
a first driver unit including a plurality of first drivers for driving a current flowing through the auxiliary pull-up driver in response to output signals of the first decoder.

9. The output driver as recited in claim 8, wherein the auxiliary pull-down driving unit includes:
a second decoder for decoding the second output value of the second detector;
an auxiliary pull-down driver for pulling down the level of the output data in response to the pull-down control signal; and
a second driver unit including a plurality of second drivers for driving a current flowing through the auxiliary pull-down driver in response to output signals of the second decoder.

10. A semiconductor device for stably driving an output data, comprising:
a first driving unit for transmitting an output data;
a detecting unit for detecting at least one of a temperature condition and a process characteristic; and
a second driving unit for controlling the output data based on detection result of the detecting unit in order to stabilize the output data.

11. The device as recited in claim 10, wherein the second driving unit includes:
an auxiliary pull-up driving unit for pulling up a level of the output data in response to the detection result of the detecting unit; and
an auxiliary pull-down driving unit for pulling down the level of the output data in response to the detection result of the detecting unit.

12. The device as recited in claim 11, wherein the first driving unit includes:
a pull-up pre-driver for pre-driving the output data to generate a pull-up control signal;
a pull-down pre-driver for pre-driving the output data to generate a pull-down control signal;
a main pull-up driver for pulling up the level of the output data in response to the pull-up control signal; and
a main pull-down driver for pulling down level of the output data in response to the pull-down control signal.

13. The device as recited in claim 12, wherein the detecting unit includes:
a temperature sensor for detecting the temperature condition;
a process characteristic sensor for detecting the process characteristic; and
an adder for adding outputs of the temperature sensor and the process characteristic sensor.

14. The device as recited in claim 12, wherein the detecting unit includes:
a first detector for detecting at least one of the temperature condition and the process characteristic to generate a first output value; and
a second detector for detecting at least one of the temperature condition and the process characteristic to generate a second output value different from the first output value.

15. The device as recited in claim 14, wherein the first detector includes:
a first temperature sensor for detecting the temperature condition;
a first process characteristic sensor for detecting the process characteristic; and
an adder for adding outputs of the first temperature sensor and the first process characteristic sensor.

16. The device as recited in claim 15, wherein the second detector includes:
a second temperature sensor for detecting the temperature characteristic to output an output value different from that of the first temperature sensor;
a second temperature sensor for detecting the process characteristic to output an output value different from that of the first process characteristic sensor; and
a second binary adder for adding outputs of the second temperature sensor and the second process characteristic sensor.

17. The device as recited in claim 16, wherein the auxiliary pull-up driving unit includes:
a first decoder for decoding the first output value of the first detector;
an auxiliary pull-up driver for pulling up the level of the output data in response to the pull-up control signal; and
a first driver unit including a plurality of first drivers for driving a current flowing through the auxiliary pull-up driver in response to output signals of the first decoder.

18. The device as recited in claim 17, wherein the auxiliary pull-down driving unit includes:
a second decoder for decoding the second output value of the second detector;
an auxiliary pull-down driver for pulling down the level of the output data in response to the pull-down control signal; and
a second driver unit including a plurality of second drivers for driving a current flowing through the auxiliary pull-down driver in response to output signals of the second decoder.

19. The device as recited in claim 18, wherein the first driver unit is configured with a plurality of PMOS transistors that are connected in parallel between a source voltage supply and the auxiliary pull-up driver and have gates receiving bits of the output signals of the first decoder unit.

20. The device as recited in claim 19, wherein the second driver unit is configured with a plurality of NMOS transistors that are connected in parallel between a ground voltage supply and the auxiliary pull-down driver and have gates receiving bits of the output signals of the second decoder unit.
